(19) United States
(12) Patent Application Publication
(10) Pub. No.: US 2018/0374911 A1
(43) Pub. Date: Dec. 27, 2018

(54) PHOTO SENSOR, DISPLAY PANEL AND DISPLAY DEVICE

(71) Applicant: BOE TECHNOLOGY GROUP CO., LTD.

(72) Inventors: Chunwei WU, Beijing (CN); Yanan JIA, Beijing (CN); Yingming LIU, Beijing (CN); Xiaoliang DING, Beijing (CN); Haisheng WANG, Beijing (CN); Xue DONG, Beijing (CN)

(21) Appl. No.: 15/781,579

(22) PCT Filed: Dec. 13, 2017
(86) PCT No.: PCT/CN2017/115918

§ 371 Date: Jun. 5, 2018

(30) Foreign Application Priority Data
May 5, 2017 (CN) 201710311762.7

(51) Int. Cl. H01L 27/32; H01L 27/12; H01L 27/142

(52) U.S. Cl. CPC H01L 27/3269; H01L 27/142; H01L 27/322; H01L 27/1214

(57) ABSTRACT

There is provided a photo sensor including a photoelectric conversion device configured to receive an optical signal and convert the optical signal into an electrical signal, and an optical processing layer located on a light incident side of the photoelectric conversion device and configured to process the optical signal to reduce the luminous flux reaching the photoelectric conversion device. The present disclosure also provides a display panel and a display device including the above-described photo sensor. The photo sensor provided in the present disclosure can be applied under high light intensity, which can increase a range of light intensity that the display device and the display panel can accurately detect.

### CROSS-REFERENCE TO RELATED APPLICATIONS

This application claims the priority of the application NO. 201710311762.7 filed on May 5, 2017 and entitled “Photo Sensor, Display Panel, and Display Device”, the entire contents of which are incorporated herein by reference.

### TECHNICAL FIELD

The present disclosure relates to the field of display technology, and in particular relates to a photo sensor, a display panel and a display device.

### BACKGROUND

In an OLED panel, a photo sensor is usually provided for fingerprint recognition, touch, and the like, thus it is desired that the photo sensor can operate accurately in various lighting environments.

### SUMMARY

There is provided a photo sensor, including: a photoelectric conversion device configured to receive an optical signal and convert the optical signal into an electrical signal; an optical processing layer, which is located on the light incident side of the photoelectric conversion device, and configured to process the optical signal to reduce luminous flux reaching the photoelectric conversion device.

In some embodiments, the optical processing layer covers at least a part of the photoelectric conversion device.

In some embodiments, a central portion of the optical processing layer is provided with an opening through which the photoelectric conversion device receives the optical signal.

In some embodiments, the optical processing layer includes a light shielding layer.

In some embodiments, the light shielding layer includes a black light shielding layer.

In some embodiments, the optical processing layer includes a filter layer.

In some embodiments, the photoelectric conversion device further includes: a photo thin film transistor configured to generate a leakage current under irradiation of the optical signal; and a storage capacitor configured to store charges generated by the leakage current.

In some embodiments, the photo sensor further includes: a readout thin film transistor configured to read out the charges, generated by the leakage current, stored in the storage capacitor when the readout thin film transistor is turned on.

There is provided a display panel, which includes the above photo sensor.

In some embodiments, the display panel includes a photo sensing area, the photo sensing area includes a plurality of photo sensors, the plurality of photo sensors have different optical processing layers from each other.

In some embodiments, the optical processing layers of the plurality of photo sensors have different light shielding areas for shielding the photoelectric conversion devices.

In some embodiments, a central portion of the optical processing layer of at least one of the plurality of photo sensors is provided with an opening through which a corresponding photoelectric conversion device receives the optical signal.

In some embodiments, the optical processing layer includes a light shielding layer.

In some embodiments, the light shielding layer includes a black light shielding layer.

In some embodiments, the optical processing layer includes a filter layer.

In some embodiments, filter layers of the plurality of photo sensors have different thicknesses from each other.

In some embodiments, the photoelectric conversion device further includes: a photo thin film transistor configured to generate a leakage current under irradiation of the optical signal; and a storage capacitor configured to store charges generated by the leakage current.

In some embodiments, the photo sensor further includes: a readout thin film transistor configured to read out the charges, generated by the leakage current, stored in the storage capacitor when the readout thin film transistor is turned on.

There is provided a display device, which includes the above display panel.

### BRIEF DESCRIPTION OF THE DRAWINGS

FIG. 1a is a structural diagram of a circuit adopting a conventional photo sensor;

FIG. 1b is a structural diagram of a display panel with a conventional photo sensor;

FIG. 2 is another structural diagram of a display panel with a conventional photo sensor;

FIG. 3 is a graph showing a relationship between a leakage current, a turn-on voltage and a light brightness corresponding to a light intensity of a conventional photo sensor;

FIG. 4 is a functional block diagram of a photo sensor according to an embodiment of the present disclosure;

FIG. 5a and FIG. 5b are structural diagrams of a photo sensor provided by an embodiment of the present disclosure;

FIG. 6 is a structural diagram of a photo sensing region of a display panel in an embodiment of the present disclosure.

### DETAILED DESCRIPTION

To enable those skilled in the art to better understand technical solutions of the present disclosure, a photo sensor, a display panel, and a display device provided in the present disclosure will be described in detail below in conjunction with the accompanying drawings.

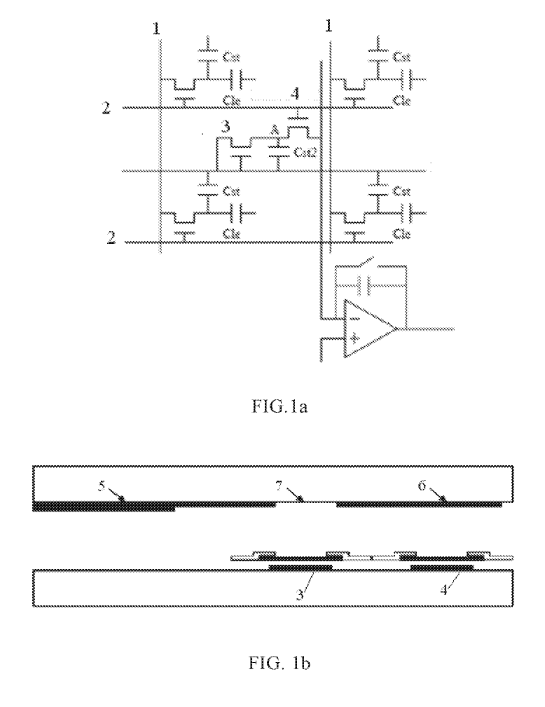

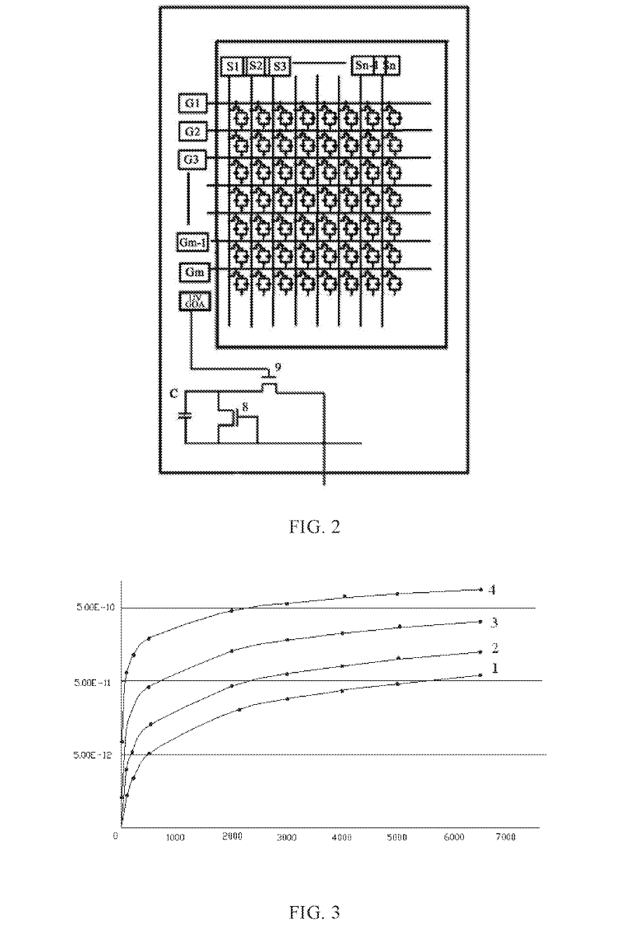

FIG. 1a and FIG. 1b are respective structural diagrams of a circuit adopting a conventional photo sensor. As shown in FIG. 1a and FIG. 1b, the conventional photo sensor integrated in the display panel is disposed in a small area within a pixel unit formed at an intersection of a data line 1 and a gate line 2, and a circuit of the photo sensor can be a 2T1C circuit, that is, includes a photo thin film transistor (photo TFT) 3 and a readout thin film transistor (readout TFT) 4, and the photo TFT 3 is configured to be turned off during a light sensing period and generate a leakage current under light and store the leakage current in a capacitor C. The readout TFT 4 is turned on every cycle to read an electrical signal stored in the capacitor so as to obtain light conditions of the photo TFT 3. As shown in FIG. 1b, the display panel includes a color filter substrate and an array substrate. The color filter substrate includes a color filter film 5, a black matrix 6 and a transparent region 7 between the color filter film 5 and the black matrix 6. The photo TFT 3 and the readout TFT 4 are disposed on the array substrate, the photo TFT 3 is disposed opposite to the transparent region 7, and the readout TFT 4 is disposed opposite to the black matrix 6. FIG. 2 is another structural diagram of a display panel with a conventional photo sensor. As shown in FIG. 2, the photo sensor includes a UV photo TFT 8, a readout TFT 9 and a capacitor C. Operation principle of the photo sensor shown in FIG. 2 is similar to that shown in FIG. 1a and FIG. 1b and will not be described here again. The photo sensor can be used to operate backlight of the display panel according to ambient light conditions. For example, in a bright environment, the backlight brightness of the display panel is lowered, and in a dark environment, the backlight brightness of the display panel is increased.

FIG. 3 is a graph showing a relationship between a leakage current, a turn-on voltage and a light brightness corresponding to a light intensity of a conventional photo sensor. The abscissa in FIG. 3 represents the light brightness corresponding to the light intensity, the ordinate represents the leakage current of the photo sensor, and curves 1-4 correspond to turn-on voltages of different photo TFTs (the turn-on voltages corresponding to the curves 1-4 are 0V-3V, respectively). It can be seen from FIG. 3 that, the leakage current changes with a change of light intensity. For example, when the light intensity is relatively low, the leakage current changes relatively large with the change of light intensity, and therefore, can be easily detected.

However, when the light intensity is relatively large (for example, the corresponding light brightness is above 4000 cd/m²), the leakage current changes smaller as the light intensity increases, thus change in the leakage current is not easily detected.

FIG. 4 is a functional block diagram of a photo sensor according to an embodiment of the present disclosure. As shown in FIG. 4, the photo sensor provided in this embodiment includes a photoelectric conversion device 10 and an optical processing layer 20. The photoelectric conversion device 10 is configured to receive an optical signal and convert the optical signal into an electrical signal. The optical processing layer 20 is disposed on the light incident side of the photoelectric conversion device 10 and the optical processing layer 20 is configured to process the optical signal to reduce luminous flux reaching the photoelectric conversion device 10, thus the photoelectric conversion device 10 can receive a smaller light intensity, so that change of the leakage current converted by the photoelectric conversion device 10 can be easily detected accurately.

In the present disclosure, since the optical processing layer 20, which is configured to process the optical signal to reduce the luminous flux reaching the photoelectric conversion device 10, is provided in the photo sensor, the optical signal with high light intensity can be processed to be with lowered light intensity and then be transmitted to the photoelectric conversion device 10. The optical signal is converted into the leakage current through the photoelectric conversion device 10 and finally detected. Therefore, the photo sensor provided in the present disclosure can be applied under high light intensity.

It should be noted that the photo sensor can determine the light condition of the current environment according to the preset relationship between the leakage current processed by the optical processing layer 20 and the intensity of the light, so as to perform subsequent operations, for example, to increase the brightness of the display panel, and so on.

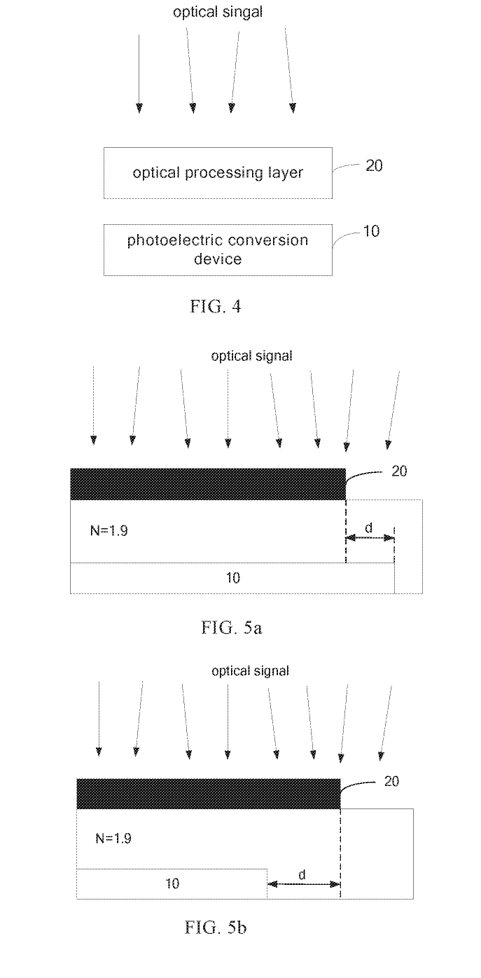

In this embodiment, as shown in FIG. 5a and FIG. 5b, the optical processing layer 20 includes a light shielding layer, so that the structure of the photo sensor is relatively simple.

Furthermore, in some implementations, the light shielding layer is a black light shielding layer, because the black light shielding layer has a strong light shielding effect, and it is convenient to quantitatively set a light shielding area shielding the photoelectric conversion device 10 by the light shielding layer.

In the embodiment, the photoelectric conversion device 10 includes a photo TFT and a storage capacitor C. The photo TFT is configured to generate a leakage current under irradiation of an optical signal, and the storage capacitor C is configured to store charges generated by the leakage current.

Furthermore, the photo sensor further includes a readout thin film transistor (Readout TFT). The Readout TFT is configured to read out the charges, generated by the leakage current, stored in the storage capacitor when it is turned on.

Since the luminous flux reaching the photoelectric conversion device 10 is correlated with the light intensity of the optical signal irradiated to the photoelectric conversion device 10, the light shielding area of the black light shielding layer determines the light intensity of the optical signal reaching the photoelectric conversion device 10. Therefore, FIG. 5a and FIG. 5 b show the relationship between the light intensity of the optical signal irradiated to the photoelectric conversion device 10 and the light shielding area shielding the photoelectric conversion device 10 by the black light shielding layer. As shown in FIG. 5a and FIG. 5b, assuming that the initial intensity of the optical signal is 1, the optical processing layer 20 is a black light shielding layer; N is a refractive index of a film layer between the optical processing layer 20 and the photoelectric conversion device 10, and N=1.9. Meanwhile setting the dimension of the photoelectric conversion device 10 in the horizontal direction of the illustration, at which the photoelectric conversion device 10 is completely exposed to light through the optical processing layer 20, is d, for example, in FIG. 5a and FIG. 5b, d is equal to a value obtained by subtracting a radial dimension of the optical processing layer 20 from a radial dimension of the photoelectric conversion device 10, where d can be positive or negative. In the case where an orthographic projection of the photoelectric conversion device 10 on the optical processing layer 20 is partially or wholly outside the optical processing layer 20, i.e., at least a part of the photoelectric conversion device 10 is completely exposed to light through the optical processing layer 20, d is a positive value. As shown in FIG. 5a, the radial dimension of the photoelectric conversion device 10 is greater than the radial dimension of the optical processing layer 20, thus d is a positive value. In contrast, in the case where an orthographic projection of the photoelectric conversion device 10 on the optical processing layer 20 is located within the optical processing layer 20, that is, the photoelectric conversion device 10 is completely shielded by the optical processing layer 20, d is a negative value. As shown in FIG. 5b, the radial dimension of the photoelectric conversion device 10 is smaller than the radial dimension of the optical processing layer 20, thus d is a negative value.

In the present disclosure, the relationship between the light intensity and d is calculated based on Fresnel diffraction, and is shown in Table 1 and Table 2 below.

TABLE 1

| Light intensity | d |
|---|---|
| (unit: 1) | (unit: μm) |
| 0.1 | −0.15 |
| 0.01 | −0.55 |
| 0.001 | −1.75 |
| 0.0001 | −5.45 |
| 0.00001 | −18 |

TABLE 2

| d | Light intensity |
|---|---|
| (unit: μm) | (unit: 1) |
| 2 | 1 |
| 0 | 1 |
| −1 | 2.93E−03 |
| −2 | 7.33E−04 |
| −3 | 3.26E−04 |
| −4 | 1.83E−04 |
| −5 | 1.17E−04 |
| −6 | 8.15E−05 |
| −7 | 5.99E−05 |
| −8 | 4.58E−05 |
| −9 | 3.62E−05 |
| −10 | 2.93E−05 |
| −11 | 2.42E−05 |

From Table 1 and Table 2, it can be directly seen that: (a) in a case where d is less than 0, the light intensity received by the photoelectric conversion device 10 gradually decreases as the absolute value of d gradually increases; (b) in a case where d is greater than or equal to 0, the light intensity received by the photoelectric conversion device 10 remains substantially constant as the absolute value of d gradually increases.

Therefore, by setting the positional relationship between the photoelectric conversion device 10 and the optical processing layer 20, the luminous flux reaching the photoelectric conversion device 10 can be controlled, thereby reducing the light intensity received by the photoelectric conversion device 10. Therefore, the leakage current of the photoelectric conversion device 10 can change significantly with a change of the light intensity.

It should be noted that, although in the embodiment of the present disclosure, the optical processing layer 20 is a light shielding layer, the present disclosure is not limited thereto. In practical applications, the optical processing layer 20 can further include a filter layer. In this case, the amount of light filtered can be controlled based on, but not limited to, the thickness of the filter layer, thereby the luminous flux reaching the photoelectric conversion device 10 can be controlled.

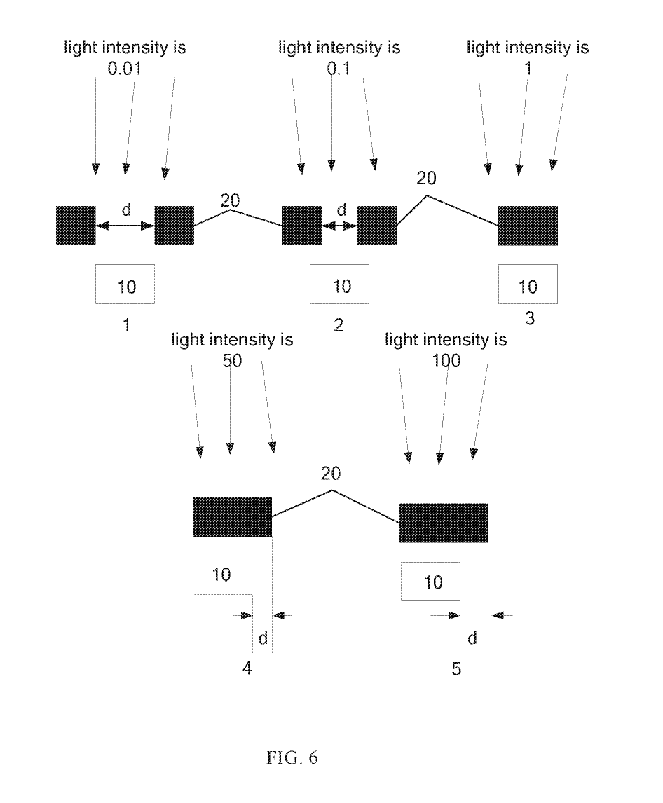

Still further, the positional relationship between the optical processing layer 20 and the photoelectric conversion device 10 can be variously set, for example, as shown in FIG. 5a and FIG. 5b, and as shown by 1 and 2 in FIG. 6. In the implementations shown by 1 and 2 in FIG. 6, the optical processing layer 20 can have an opening (a slit or a through hole) in a central portion thereof, and the photoelectric conversion device 10 receives the light irradiated from the opening. The above various settings can reduce the light intensity of the light irradiated onto the photoelectric conversion device 10.

In the embodiment, since an optical processing layer is provided in the photo sensor for processing the optical signal to reduce the luminous flux reaching the photoelectric conversion device, the optical signal with high light intensity can be weakened and then transmitted to the photoelectric conversion device. The photoelectric conversion device converts the optical signal into the leakage current and the leakage current is finally detected. Therefore, the photo sensor provided by the present disclosure can be applied under high light intensity.

An embodiment of the present disclosure further provides a display panel including the photo sensor provided in the above embodiment.

In some embodiments, the display panel includes at least one photo sensing area including a plurality of photo sensors having different optical processing layers so that different photo sensors can accurately measure different light intensity ranges, so that the range of light intensity that can be accurately detected by the display panel is significantly increased. In practical applications, a suitable detection result of the corresponding photo sensor can be selected according to the light intensity to control the backlight.

Specifically, in the case where the optical processing layer of the photo sensor is a light shielding layer, the light shielding areas of the light shielding layers that shield the photoelectric conversion device 10 are different. More specifically, as shown in FIG. 6, the photo sensing area includes five photo sensors (1-5 respectively) provided with different optical processing layers 20 respectively, as described above, since in a case where d is less than 0, with the absolute value of d gradually increases, the light intensity received by the photoelectric conversion device 10 remains substantially unchanged, and the luminous flux received by the photoelectric conversion device 10 has a positive correlation with the absolute value of d, thus, for example, for the photo sensors 1 and 2 shown in FIG. 6, d>0, in a case where, the light intensity of the environment where the photo sensor 1 is located is set to 0.01 and the light intensity of the environment where the photo sensor 2 is located is set to 0.1, in order to ensure that both the photo sensors 1 and 2 can accurately detect the leakage current in the respective environment, it is required more luminous flux to reach the photoelectric conversion device 10 in an environment where the light intensity is relatively small. Therefore, the value of d of the photo sensor 1 is greater than that of the photo sensor 2. In addition, in FIG. 6, the light intensity of the environment where the photo sensor 3 is located is set to 1, the light intensity of the environment where the photo sensor 4 is located is set to 50, the light intensity of the environment where the photo sensor 5 is located is set to 100, based on the relationship (a) obtained in the above embodiment and a small light intensity being required to reach the photoelectric conversion device 10 in a large light intensity environment, the photo sensor 3 can be set to have d=0, the photo sensors 4 and 5 can be set to have d<0, and the absolute value of d of the photo sensor 5 is greater than that of the photo sensor 4.

More specifically, in the case where the optical processing layer of the photo sensor is a filter layer, the thicknesses of the filter layers of the plurality of photo sensors are different so that the luminous fluxes of light reaching the respective photoelectric conversion devices under a same light intensity are different. In particular, in the case where a filter layer is used as the optical processing layer, the photo sensors having different luminous fluxes of light can be realized by setting different thicknesses for filter layers of the photo sensors, therefore, providing an opening in the central portion of the filter layer for the photo sensor is not inevitable.

In addition, the present disclosure also provides a display panel including the photo sensor provided in the above embodiments of the present disclosure. Therefore, the display panel can be applied in a high light intensity environment, so that the range of light intensity that the display panel can accurately detect can be greatly increased.

In addition, embodiments of the present disclosure further provide a display device including the display panel provided in the above disclosure.

The display device includes, but is not limited to, any product or component with a display function such as a mobile phone, a tablet computer, a television, a monitor, a notebook computer, a digital photo frame, a navigator, and the like.

The display device provided in the embodiment of the present disclosure includes the display panel provided in the above embodiments of the present disclosure. Therefore, the display device can be applied in a high light intensity environment, so that the range of light intensity that the display device can accurately detect can be greatly increased.

It should be understood that, the foregoing embodiments are only exemplary embodiments used for explaining the principle of the present disclosure, but the present disclosure is not limited thereto. Various variations and modifications may be made by a person skilled in the art without departing from the spirit and essence of the present invention, and these variations and modifications also fall into the protection scope of the present disclosure.

1. A photo sensor, comprising:
a photoelectric conversion device configured to receive an optical signal and convert the optical signal into an electrical signal;
an optical processing layer, which is provided on a light incident side of the photoelectric conversion device, and configured to process the optical signal to reduce a luminous flux reaching the photoelectric conversion device.

2. The photo sensor according to claim 1, wherein the optical processing layer covers at least a part of the photoelectric conversion device.

3. The photo sensor according to claim 2, wherein a central portion of the optical processing layer is provided with an opening through which the photoelectric conversion device receives the optical signal.

4. The photo sensor according to claim 1, wherein the optical processing layer includes a light shielding layer.

5. The photo sensor according to claim 4, wherein the light shielding layer includes a black light shielding layer.

6. The photo sensor according to claim 1, wherein the optical processing layer includes a filter layer.

7. The photo sensor according to claim 1, wherein the photoelectric conversion device further includes:
a photo thin film transistor configured to generate a leakage current under irradiation of the optical signal; and
a storage capacitor configured to store charges generated by the leakage current.

8. The photo sensor according to claim 7, wherein the photo sensor further includes:
a readout thin film transistor configured to read out the charges, generated by the leakage current, stored in the storage capacitor when the readout thin film transistor is turned on.

9. A display panel, which comprises at least one photo sensor of claim 1.

10. The display panel according to claim 9, which includes a photo sensing area and a plurality of photo sensors, wherein the plurality of photo sensors are provided in the photo sensing area, and the plurality of photo sensors have different optical processing layers from each other.

11. The display panel according to claim 10, wherein the optical processing layers of the plurality of photo sensors have different light shielding areas for shielding the photoelectric conversion devices.

12. The display panel according to claim 11, wherein a central portion of the optical processing layer of at least one of the plurality of photo sensors is provided with an opening through which a corresponding photoelectric conversion device receives the optical signal.

13. The display panel according to claim 9, wherein the optical processing layer includes a light shielding layer.

14. The display panel according to claim 13, wherein the light shielding layer includes a black light shielding layer.

15. The display panel according to claim 9, wherein the optical processing layer includes a filter layer.

16. The display panel according to claim 15, wherein filter layers of the plurality of photo sensors have different thicknesses from each other.

17. The display panel according to claim 9, wherein the photoelectric conversion device further includes:
a photo thin film transistor configured to generate a leakage current under irradiation of the optical signal; and
a storage capacitor configured to store charges generated by the leakage current.

18. The display panel according to claim 17, wherein the photo sensor further includes:
a readout thin film transistor configured to read out the charges, generated by the leakage current, stored in the storage capacitor when the readout thin film transistor is turned on.

19. A display device, which comprises the display panel according to claim 9.

20. A display device, which comprises the display panel according to claim 10.
